(19) United States
(12) Patent Application Publication
(10) Pub. No.: US 2026/0313971 A1
(43) Pub. Date: Oct. 8, 2026

(54) FORMING ISOLATION REGIONS WITH LOW PARASITIC CAPACITANCE AND REDUCED DAMAGE

(71) Applicant: Taiwan Semiconductor Manufacturing Co., Ltd., Hsinchu (TW)

(72) Inventors: Tzu-Ging Lin, Kaohsiung City (TW); Chun-Liang Lai, Hsinchu (TW); Yun-Chen Wu, Hsinchu (TW)

(21) Appl. No.: 19/713,964

(22) Filed: Jun. 19, 2026

Related U.S. Application Data
(63) Continuation of application No. 18/591,792, filed on Feb. 29, 2024.
(60) Provisional application No. 63/590,813, filed on Oct. 17, 2023.

(51) Int. Cl. H10D 30/67; H10D 30/01; H10D 30/43; H10D 62/10; H10D 62/13; H10D 64/01; H10D 84/01; H10D 84/03; H10D 84/83

(52) U.S. Cl. CPC H10D 30/6735; H10D 30/014; H10D 30/43; H10D 30/6757; H10D 62/115; H10D 62/118; H10D 62/151; H10D 64/017; H10D 84/0135; H10D 84/0151; H10D 84/038; H10D 84/83

(57) ABSTRACT

A structure includes a plurality of semiconductor regions, a first gate stack and a second gate stack immediately neighboring each other, a first fin isolation region in the first gate stack, and a second fin isolation region in the second gate stack. The first fin isolation region and the second fin isolation region have a sideway overlap having an overlap distance being equal to or greater than a pitch of the plurality of semiconductor regions. The overlap distance is measured in a direction parallel to lengthwise directions of the first gate stack and the second gate stack. A plurality of source/drain regions are on opposing sides of the first gate stack and the second gate stack to form a plurality of transistors.

### PRIORITY CLAIM AND CROSS-REFERENCE

This application is a continuation of U.S. patent application Ser. No. 18/591,792, filed Feb. 29, 2024 and entitled “FORMING ISOLATION REGIONS WITH LOW PARASITIC CAPACITANCE AND REDUCED DAMAGE,” which claims the benefit of U.S. Provisional Application No. 63/590,813, filed on Oct. 17, 2023, and entitled “BEAT THE SCALING LIMIT IN THE INTERSECTION OF CPODE CUTS,” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

The formation of the GAA transistors typically includes forming long strips (including alternating semiconductor materials) and long gate stacks, and then forming isolation regions to cut the long strips and long gate stacks into shorter portions. The shorter portions may be used to form the channel layers and the gate stacks of the GAA transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11A, 11B 12A, 12B, 12C, 12D, 13A, 13B, 14A, 14B, 15A, 15B, 15C, 15D, 15E, 16A, 16B, 16C, 17A, 17B, 18A, 18B, 18C, 19, 20, 21A, 21B, 22A, 22B, 23A, and 23B illustrate the views of intermediate stages in the formation of Gate-All-Around (GAA) transistors in accordance with some embodiments.

FIGS. 24A, 24B, 25A, 25B, 26A, 26B, 27A, 27B, 28A, 28B, 29A, 29B, 30A, and 30B illustrate the formation of Continuous Polysilicon on Diffusion edge (CPODE) regions with dummy fins in accordance with some embodiments.

FIG. 31 illustrates a process flow for forming GAA transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors and the respective Continuous Polysilicon on Diffusion edge (CPODE) isolation regions, Continuous Metal on Diffusion edge (CMODE) isolation regions, and the method of forming the same are provided. In accordance with some embodiments of the present disclosure, the CPODE isolation regions (or CMODE isolation regions) on neighboring gate stacks have overlaps in the gate length direction. This results in wider photoresist strips in the photoresist that is used for the patterning of the CPODE/CMODE regions. With the wider photoresist strips being formed, the possibility of the collapse of the photoresist strips is reduced, and the defect rate is reduced.

In the illustrated embodiments, the formation of GAA Transistors is used as an example to explain the concept of the present disclosure. Other types of transistors such as Fin Field-Effect Transistors (FinFETs), planar transistors, or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

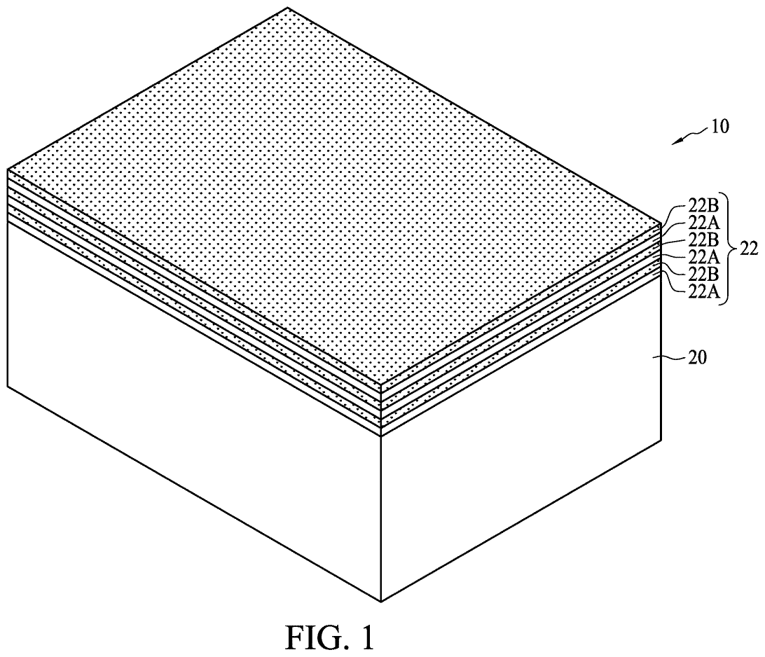

FIGS. 1-4, 5A, 5B, 6A, 6B, 7A, 7B, 8A, 8B, 9A, 9B, 10A, 10B, 10C, 11A, 11B 12A, 12B, 12C, 12D, 13A, 13B, 14A, 14B, 15A, 15B, 15C, 15D, 15E, 16A, 16B, 16C, 17A, 17B, 18A, 18B, 18C, 19, 20, 21A, 21B, 22A, and 22B illustrate the views of intermediate stages in the formation of GAA transistors in accordance with some embodiments of the present disclosure. The corresponding processes are also reflected schematically in the process flow shown in FIG. 22.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

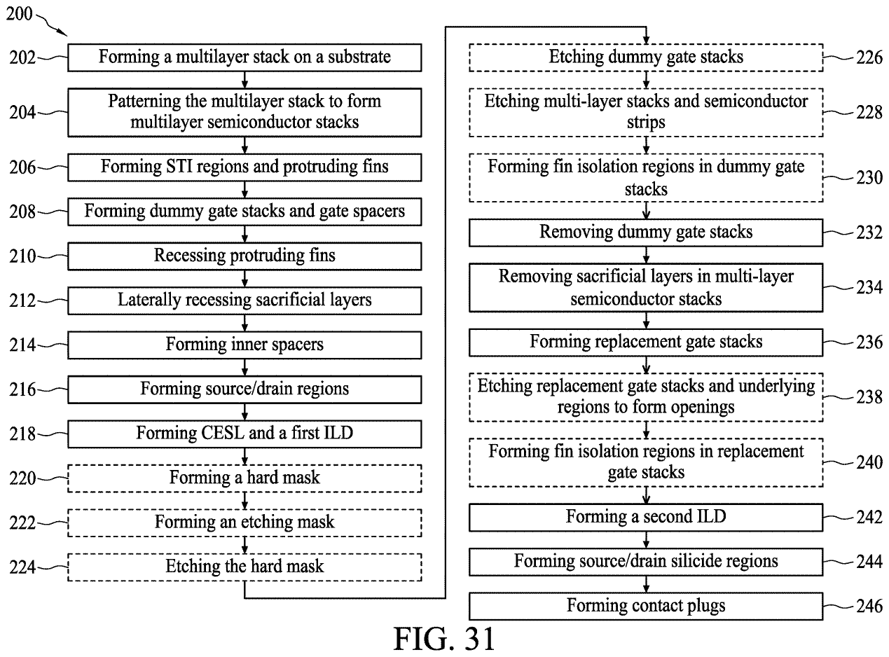

In accordance with some embodiments, multilayer stack 22 is formed through a series of deposition processes for depositing alternating materials. The respective process is illustrated as process 202 in the process flow 200 shown as in FIG. 31. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

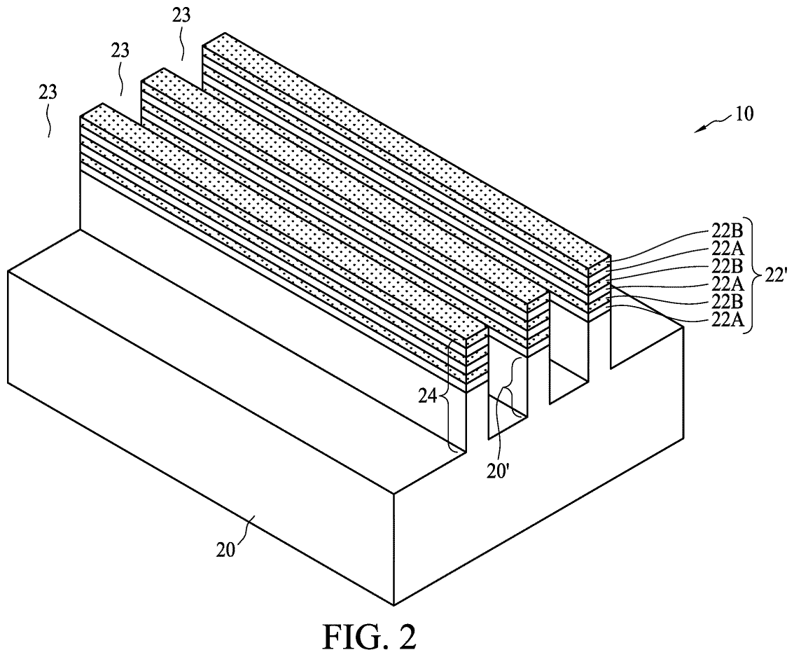

Referring to FIG. 2, multilayer stack 22 and a portion of the underlying substrate 20 are patterned in an etching process(es), so that trenches 23 are formed. The respective process is illustrated as process 204 in the process flow 200 shown as in FIG. 31. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

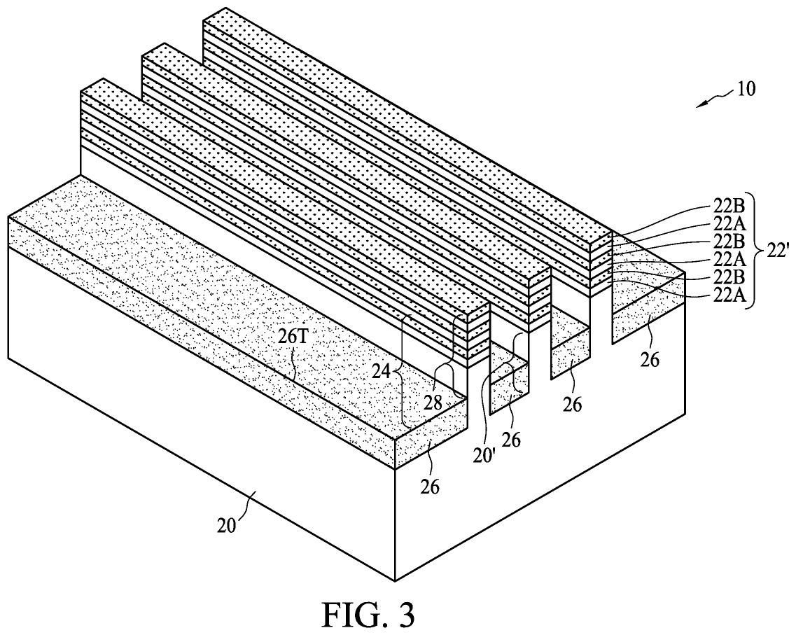

FIG. 3 illustrates the formation of isolation regions 26, which are also referred to as Shallow Trench Isolation (STI) regions throughout the description. The respective process is illustrated as process 206 in the process flow 200 shown as in FIG. 31. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

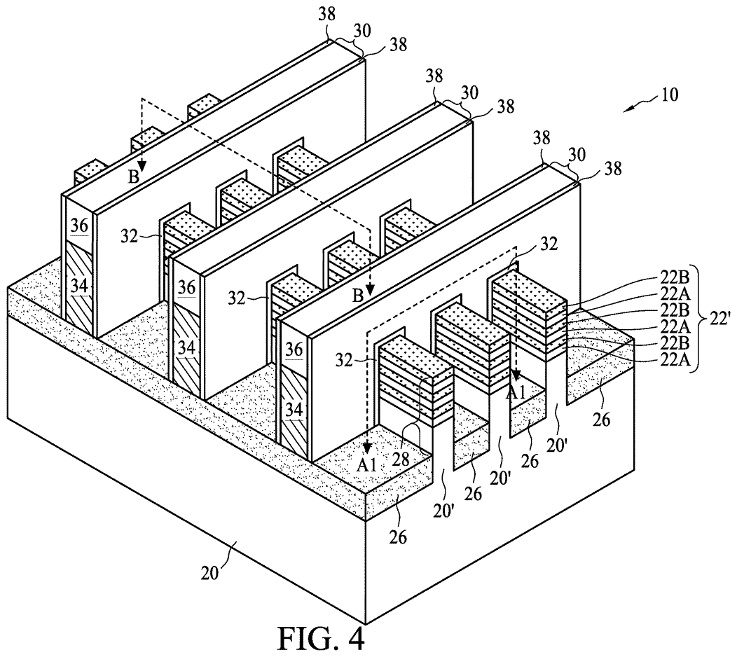

Referring to FIG. 4, dummy gate stacks 30 and gate spacers 38 are formed on the top surfaces and the sidewalls of (protruding) fins 28. The respective process is illustrated as process 208 in the process flow 200 shown as in FIG. 31. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon dioxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

In accordance with alternative embodiments, one or more layers of gate spacers 38 may be formed using the processes as illustrated in FIG. 19, and the resulting layer of gate spacers 38 comprises the material as discussed referring to FIGS. 19 through 21A and 21B. For example, gate spacers 38 may be formed of or include SiOCNH therein. The details of the formation processes are discussed in subsequent paragraphs.

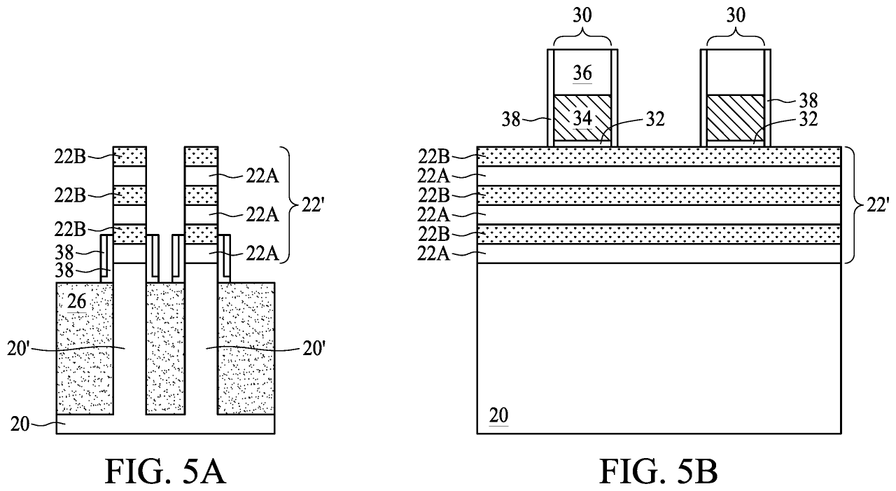

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. Gate spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

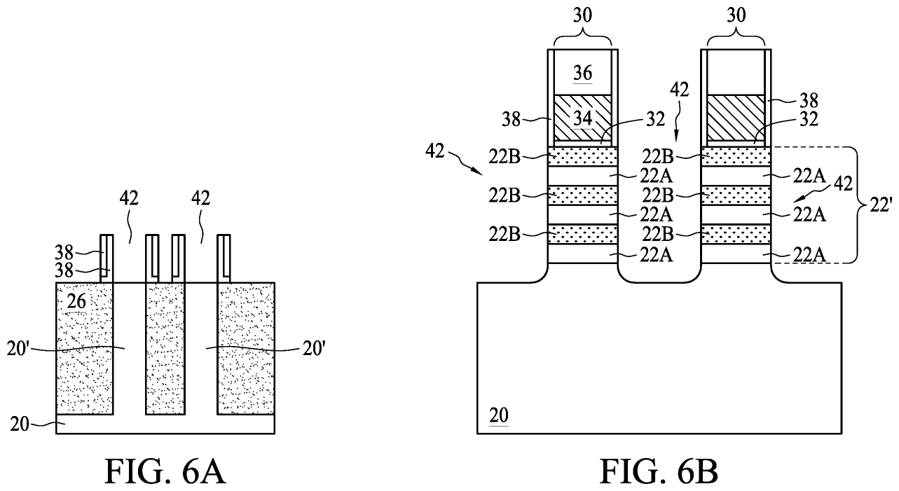

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown as in FIG. 31. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

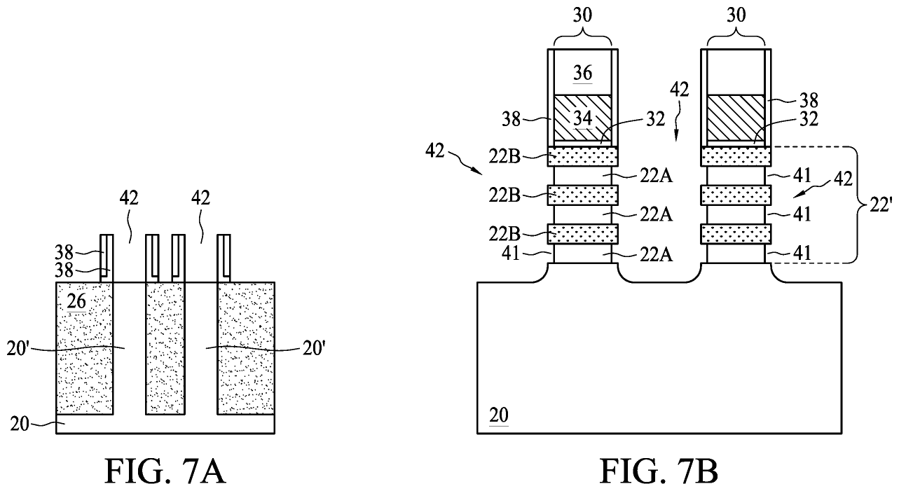

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown as in FIG. 31. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

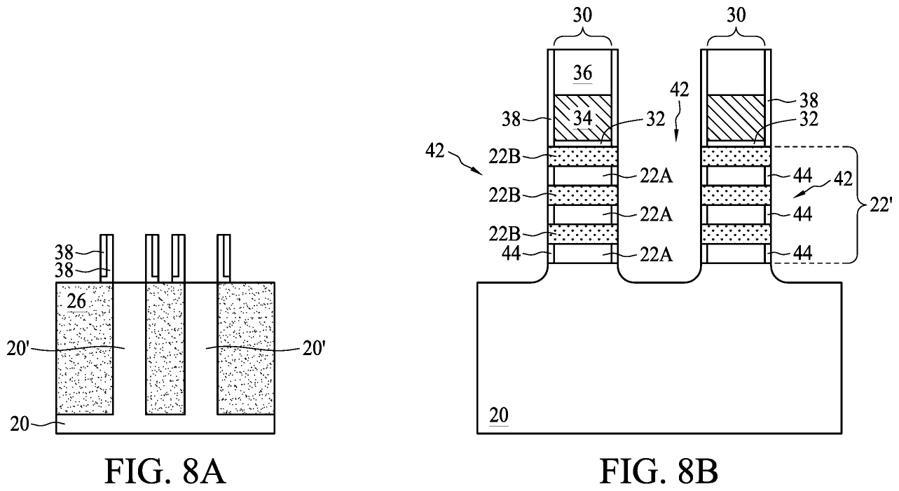

Referring to FIGS. 8A and 8B, inner spacers 44 are formed. The respective process is illustrated as process 214 in the process flow 200 shown as in FIG. 31. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

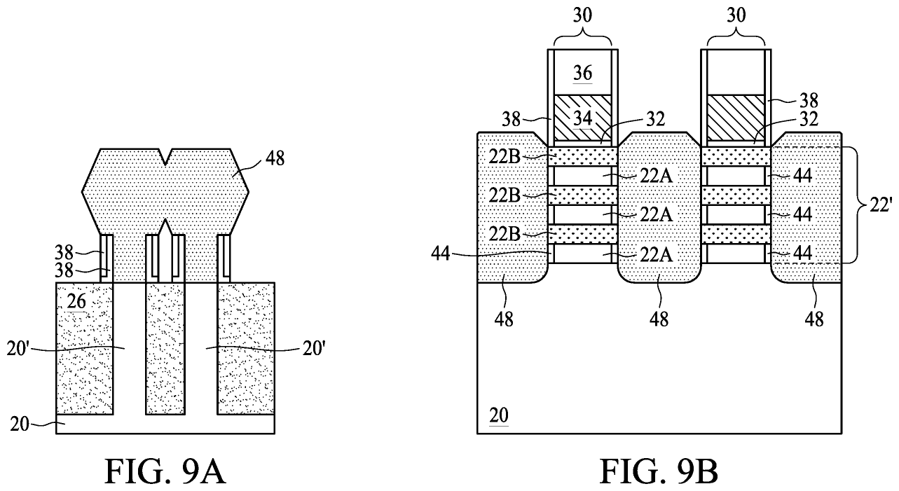

FIGS. 9A and 9B illustrate the cross-sectional views and a perspective view in the formation of source/drain regions 48 in recesses 42 through epitaxy. The respective process is illustrated as process 216 in the process flow 200 shown as in FIG. 31. Source/drain region(s) may refer to a source or a drain, individually or collectively dependent upon the context. In accordance with some embodiments, the source/drain regions 48 may exert stress on the nanostructures 22B, which are used as the channels of the corresponding GAA transistors, thereby improving performance.

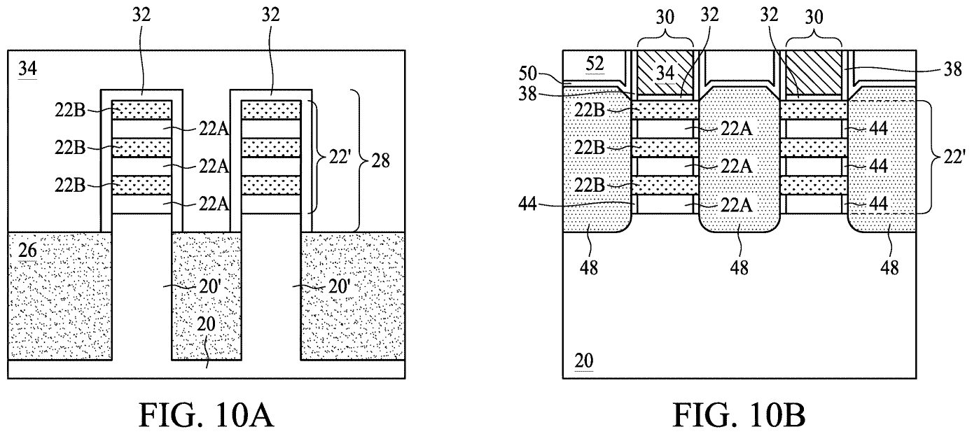

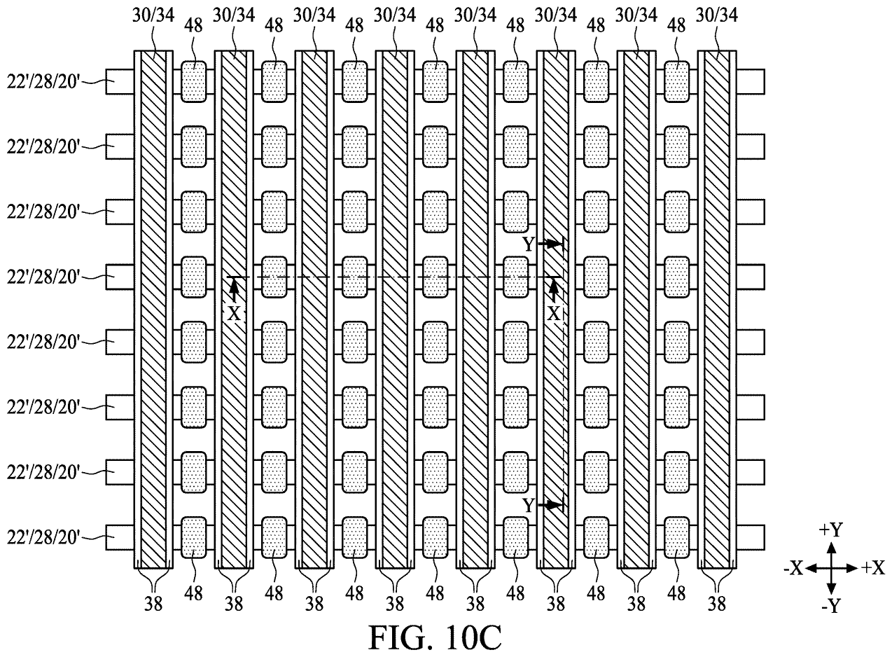

In accordance with some embodiments, the corresponding transistor is n-type, and epitaxial source/drain regions 48 are accordingly formed as n-type by doping an n-type dopant. For example, silicon phosphorous (SiP), silicon carbon phosphorous (SiCP), or the like may be grown to form epitaxial source/drain regions 48. In accordance with alternative embodiments, the corresponding transistor is p-type, and epitaxial source/drain regions 48 are accordingly formed as p-type by doping a p-type dopant. For example, silicon boron (SiB), silicon germanium boron (SiGeB), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other, with voids 49 (FIG. 10C) being formed.

After the epitaxy process, epitaxy regions 48 may be further implanted with an n-type impurity or a p-type impurity to form source and drain regions, which are also denoted using reference numeral 48. In accordance with alternative embodiments of the present disclosure, the implantation process is skipped when epitaxy regions 48 are in-situ doped with the n-type impurity or p-type impurity during the epitaxy, and the epitaxy regions 48 are also source/drain regions.

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown as in FIG. 31. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard mask layers 36 to reveal dummy gate electrodes 34, as shown in FIG. 10A. In accordance with alternative embodiments, the planarization process may reveal, and is stopped on, hard mask layers 36. In accordance with some embodiments, after the planarization process, the top surfaces of dummy gate electrodes 34 (or hard mask layers 36), gate spacers 38, and ILD 52 are level within process variations.

FIG. 10C illustrates a top view of the structure shown in FIGS. 10A and 10B in accordance with some embodiments. Multilayer stacks 22′, substrate strips 20′, and protruding fins 28 (refer to FIG. 10A) have lengthwise directions in (parallel to) the X-direction, and the corresponding cross-sectional view is referred to as the X-cut view. Dummy gate stacks 30, which include dummy gate electrodes 34 (such as polysilicon strips) have lengthwise directions in (parallel to) the Y-direction, and the corresponding cross-sectional view is referred to as the Y-cut view. Source/drain regions 48 are formed based on some portions of the multilayer stacks 22′ (as viewed in FIGS. 5B and 10B). The edges of source/drain regions may be in contact with, or may be spaced apart from, gate spacers 38.

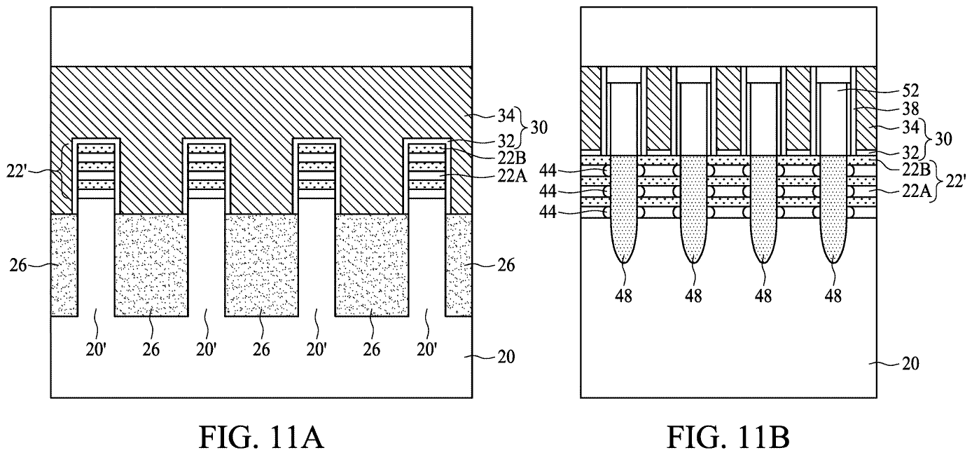

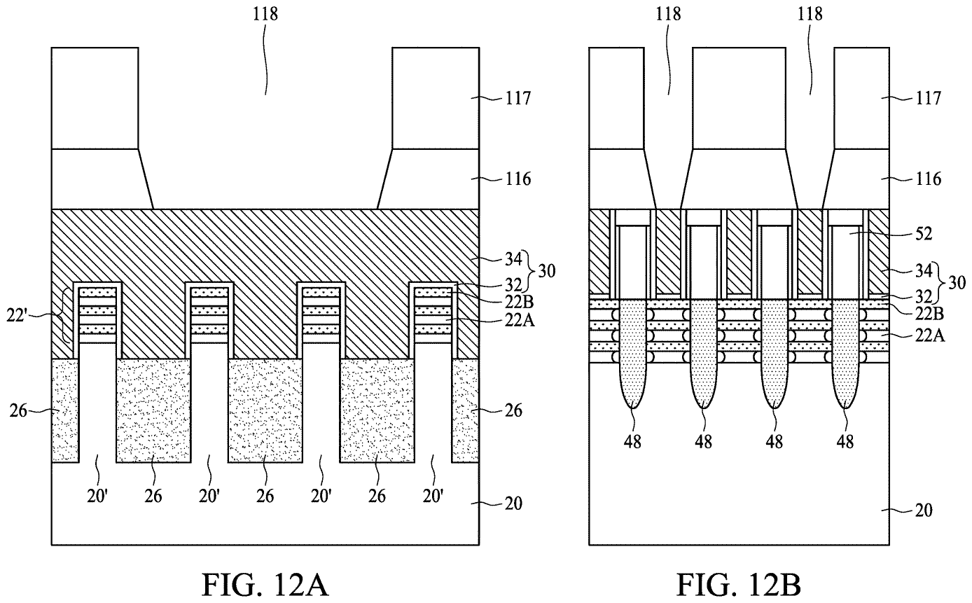

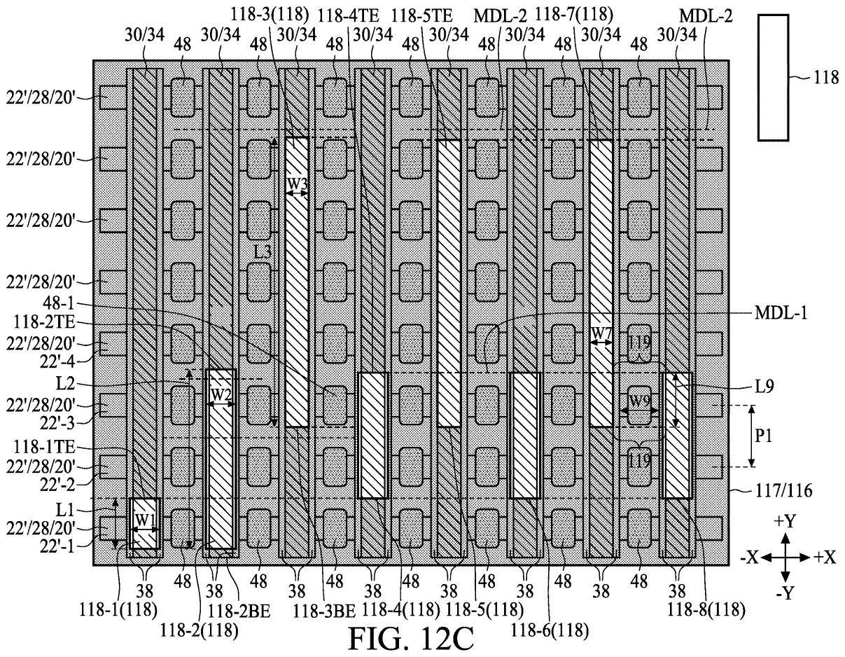

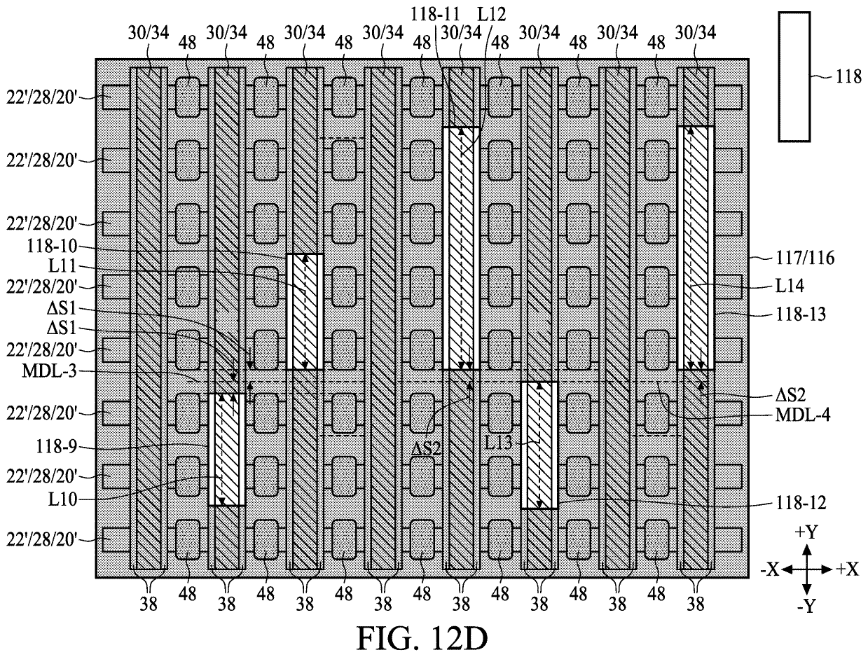

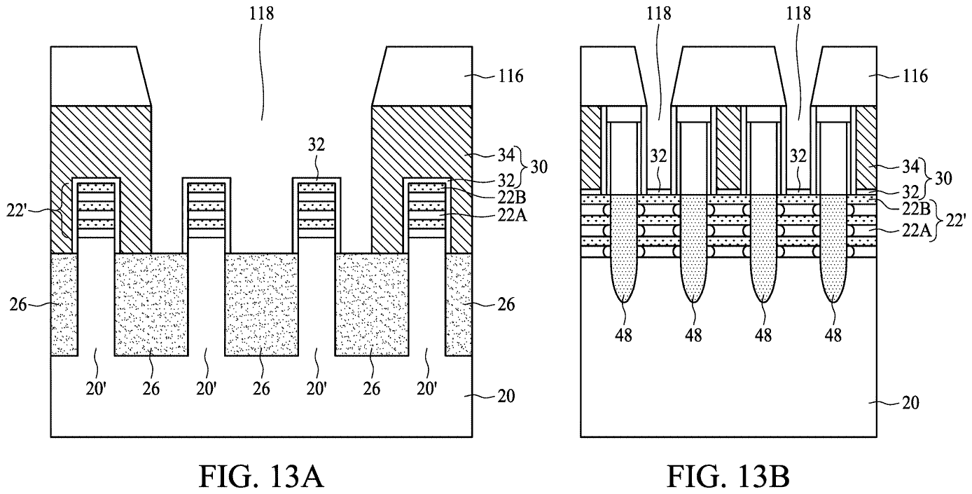

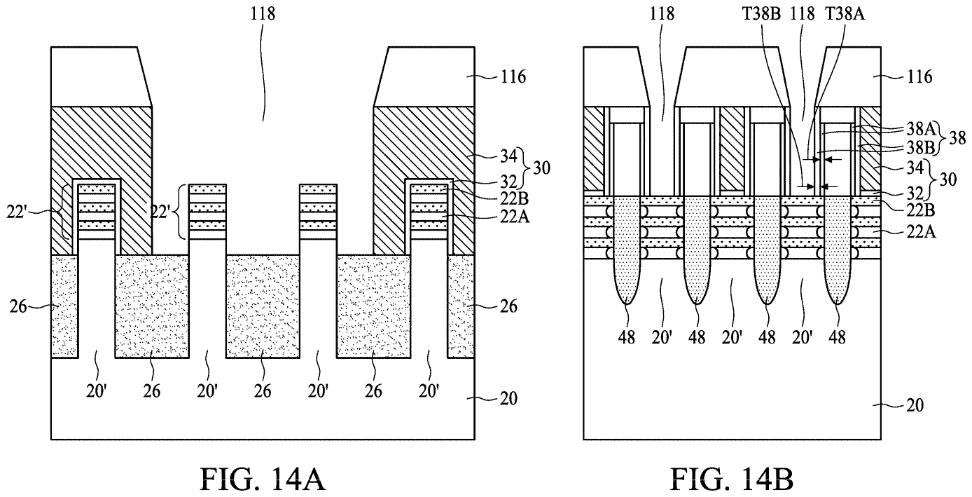

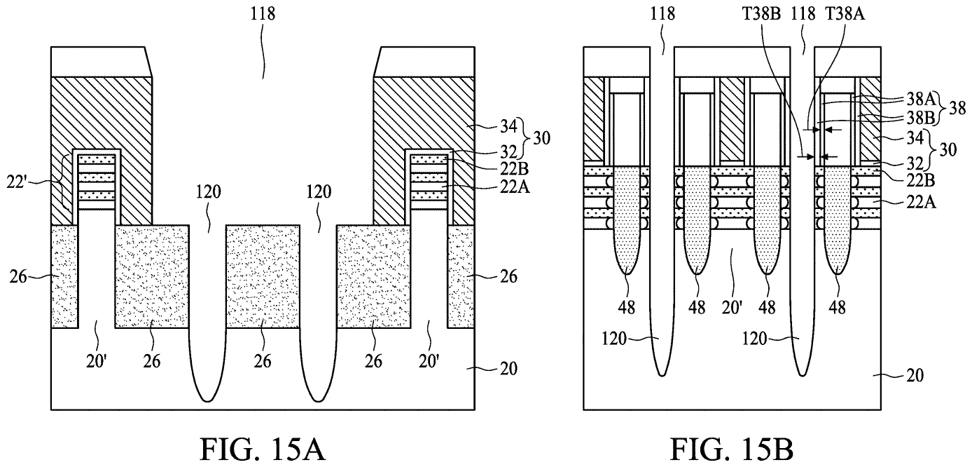

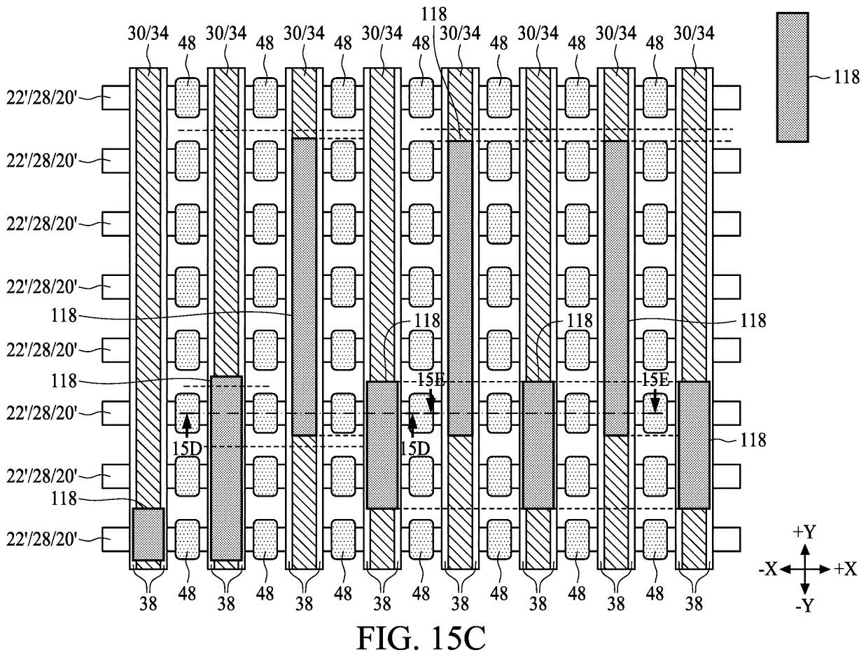

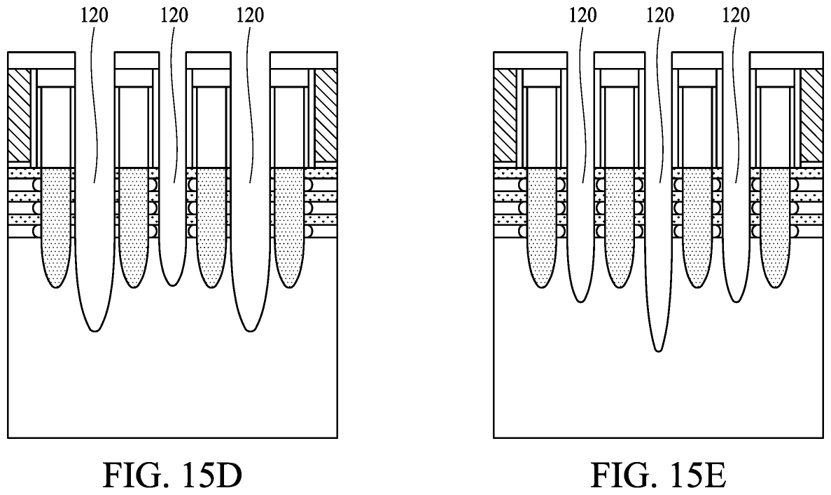

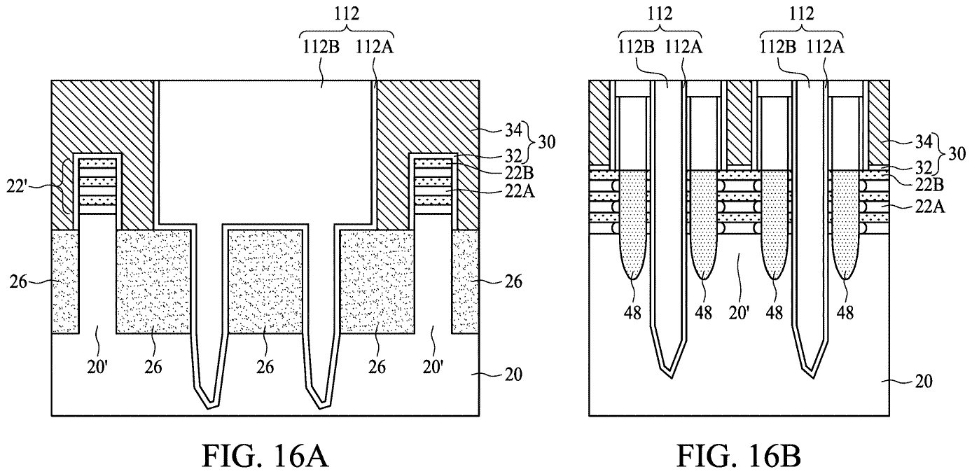

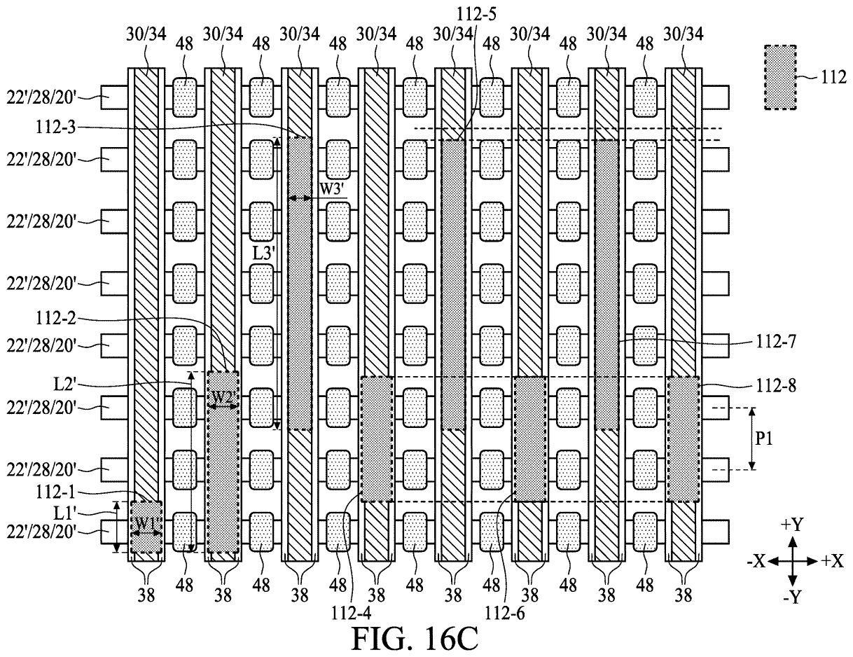

FIGS. 11A and 11B through FIGS. 16A, 16B, ad 16C illustrate the top views and cross-sectional views in the formation of fin isolation regions 112, which are Continuous Polysilicon on Diffusion edge (CPODE) regions in accordance with these embodiments. The name “fin isolation regions” is used due to that the CPODE regions and CMODE regions are formed to cut the protruding fins 28 and the underlying semiconductor strips. In subsequent figures, the figures having letter A following the corresponding figure numbers are obtained from the Y-cut (along Y-direction) in FIG. 10C or FIGS. 21A and 21B, while the figures having letter B following the corresponding figure numbers are obtained from the X-cut (along X-direction) in FIG. 10C or FIGS. 21A and 21B.

In accordance with some embodiments, the formation of fin isolation regions 112 involves cutting dummy gate stacks 30, multilayer stacks 22′, and substrate strips 20′. In accordance with alternative embodiments, as shown in FIGS. 18C, 19, and 20, the fin isolation regions 112 are formed by cutting replacement gate stacks 70 and the underlying semiconductor regions. The fin isolation regions 112 thus will be CMODE regions. Accordingly, the processes 222-230 and processes 238-240 in FIG. 31 are shown as being dashed to indicate that one of the CPODE process or CMODE process may be performed, while the other may not be performed.

FIGS. 11A and 11B illustrate the structure in FIG. 10C, and are obtained from the cross-sections Y-cut and X-Cut, respectively. FIGS. 11A and 11B also correspond to FIGS. 10A and 10B, respectively. Accordingly, FIG. 11A illustrates multi-layer stacks 22′, and dummy gate stack 30 on multi-layer stacks 22′. FIG. 11B illustrates source/drain regions 48, multi-layer stacks 22′, inner spacers 44, and dummy gate stacks 30.

Referring to FIGS. 12A and 12B, hard mask 116 is formed. The respective process is illustrated as process 220 in the process flow 200 shown as in FIG. 31. Hard mask 116 may comprise a dielectric material such as SiN, silicon, or the like, or multi-layers thereof. Etching mask 117 is formed over hard mask 116. The respective process is illustrated as process 222 in the process flow 200 shown as in FIG. 31. In accordance with some embodiments, etching mask 117 includes a patterned photoresist (and is alternatively referred to as photoresist 117) with openings 118 therein, and may or may not include other layers such as bottom anti-reflective coating. Etching mask 117 may also be a dual layer etching mask or a tri-layer etching mask. Hard mask 116 is etched, so that openings 118 penetrate through hard mask 116.

FIG. 12C illustrates a top view of etching mask 117 and hard mask 116 having openings 118 (including 118-1 through 118-8) formed therein in accordance with some embodiments. The respective process is illustrated as process 224 in the process flow 200 shown as in FIG. 31. It is appreciated that the plurality of openings 118 are directly on dummy gate stacks 30, and may or may not extend directly over gate spacers 38. Openings 118 may be elongated, with the lengthwise directions being parallel to (in) the lengthwise direction of dummy gate stacks 30 (and dummy gate electrodes 34).

Throughout the description, for the simplicity of discussion, the “+Y” direction is referred to as an “up” direction, and the “−Y” direction is referred to as a “down” direction. In accordance with some embodiments, when two openings 118 are on immediately neighboring dummy gate stacks 30 and extend to the spaces between two neighboring multi-layer stacks 22′, the two openings 118 cross the same multi-layer stack 22′. Throughout the description, when two gate stacks (or openings) are described as being “immediately neighboring” gate stacks, it means that there are no gate stacks (or openings) between them. The openings on or extending into the immediately neighboring gate stacks are also referred to as “immediately neighboring” openings. For example, both of openings 118-2 and 118-3 intersects multi-layer stack 22′-3, and both of openings 118-1 and 118-2 intersect multi-layer stack 22′-1.

In accordance with alternative embodiments, the openings 118 on immediately neighboring dummy gate stacks 30 may intersect two or more multi-layer stacks 22′. For example, FIG. 12C illustrates that both of openings 118-2 and 118-3 intersect multi-layer stack 22-3, while in alternative embodiments, opening 118-2 may extend upwardly in the +Y direction, so that both of openings 118-2 and 118-3 intersect multi-layer stacks 22-3 and 22-4.

Alternatively stated, the top end 118-2TE of opening 118-2 extends beyond the bottom end 118-3BE (the end in the −Y direction) of opening 118-3 in the +Y direction. Also, the top end 118-1TE of opening 118-1 extends beyond the bottom end 118-2BE (the end in the −Y direction) of opening 118-2 in the +Y direction. This may also be interpreted that when viewing the openings 118 from left to right (or from right to left), opening 118-2 has the bottom portion intersecting (also referred to as sideway overlapping when viewed from left to right) ab entire opening 118-1, and opening 118-2 has the top portion intersecting (sideway overlapping) the bottom portion of opening 118-3.

Similarly, other openings 118 may have their top ends and/or bottom ends extend beyond the bottom ends and/or top ends, respectively, of the openings 118 on their immediately neighboring dummy gate stacks 30.

Due to the sideway overlapping of immediately neighboring openings 118, the epitaxy region 48 between them are not used for forming transistors. For example, epitaxy region 48-1 is between openings 118-2 and 118-3, and hence is fully encircled by dielectric materials, and is not a part of any transistor.

In accordance with some embodiments, longer openings 118 (with lengthwise direction in the gate length direction) are designed to be narrower and have smaller widths. For example, openings 118-1, 118-2, and 118-3 have lengths L1, L2, and L3, respectively, and widths W1, W2, and W3, respectively. The sizes of openings 118 are design to have the relationship L3>L2>L1. Accordingly, the widths are designed to have the relationship W3<W2<W1 to fit the differences in lengths. Alternatively stated, the longer openings 118 are made narrower, and vice versa. This will advantageously result in reduced possibility of photoresist collapse and delamination. For example, openings 118-7 and 118-8 have a photoresist portion in between and in region 119, which has length L9 and width W9. This portion of photoresist is small and prone to collapse.

By reducing the width W7 of the longer openings 118, the width W9 of the portion of photoresist 117 in region 119 is increased, and thus is less likely to collapse. Furthermore, by making the neighboring openings sideway overlap in their lengthwise direction, the lengths of the portion of photoresist 117 in between is longer. For example, length L9 of the portion of the photoresist 117 in region 119 may be great enough so that this portion of the photoresist 117 is less likely to collapse. Otherwise, if the top end of opening 118-8 retreats in the −Y direction, and/or the bottom end of opening 118-7 retreats in the +Y direction, length L9 is reduced and this this portion of the photoresist 117 is more likely to collapse. When the top end of opening 118-8 has the same Y-value as the bottom end of opening 118-7, process error may occur, and an opening may even be formed connecting opening 118-7 to opening 118-8.

In accordance with some embodiments, throughout the wafer 10, a threshold length is determined, and throughout the wafer 10 and the respective device die, the openings 118 with lengths smaller than the threshold length are referred to as short openings, while the openings 118 with lengths equal to or greater than the threshold length are referred to as long openings. The short openings 118 are designed to have a first width, and the long openings 118 with the lengths equal to or greater than the threshold length are designed to have a second width smaller than the first width.

In accordance with alternative embodiments, instead of having one threshold length and thus two length ranges, there may be a first threshold length and a second threshold length greater than the first threshold length. Throughout the wafer 10 and the respective device die, the openings 118 with the lengths smaller than the first threshold length may be short openings having a first width. The openings with the lengths equal to or greater than the first threshold length but smaller than the second threshold length may be mid-length openings having a second width smaller than the first width. The openings with the lengths equal to or greater than the second threshold length may be long openings having a third width smaller than the second width. There may also be three or more threshold lengths and corresponding length ranges, and their widths are accordingly designed to have an inversed trend as discussed above.

In accordance with some embodiments, the distance of an opening extending beyond its neighboring opening (in the +Y or −Y direction) is referred to as “overlap distance” of the sideway overlap. For example, openings 118-7 and 118-8 have overlap distance L9. The overlap distances between immediately neighboring openings 118 may be equal to or greater than the pitch P1 of neighboring active regions (such as multi-layer stacks 22′) to reliably reduce the possibility of photoresist collapsing. The overlap distances may also be n*P1, with n being an integer or non-integer equal to or greater than 1 (2, 3, 4, 5, or more). In addition, shorter openings may have their ends aligned to the middle between neighboring epitaxy regions 48. For example, the top end 118-4TE of opening 118-6 is aligned to the middle line MDL-1, while the top end 118-5TE of opening 118-5 is offset from the middle line MDL-2.

FIG. 12D illustrates the top view of the structure including a non-overlapping embodiment in accordance with some embodiments. Openings 118-9 through openings 118-13 are formed in etching mask 117, and may be on the same wafer (and same device die) as the openings 118 as shown in FIG. 12C. In accordance with some embodiments, openings 118-9 and 118-10 are on neighboring dummy gate stacks 30, and have the same length L10. Openings 118-9 and 118-10 also extend on two neighboring multi-layer stacks 22′, and both extend into the same space between the two neighboring multi-layer stacks 22′. The middle line between the neighboring multi-layer stacks 22′ is MDL-3.

To reduce the defect in etching mask 117, both ends of openings 118-9 and openings 118-10 are recessed away from the middle line MDL-3 in accordance with some embodiments. For example, both of openings 118-9 and openings 118-10 recess from the middle line MDL-3 in Y-direction by the same distance ΔS1, which may be in the range between about 1 nm and about 5 nm. Both of openings 118-9 and 118-10, however, still extend into the same space between the two neighboring multi-layer stacks 22′.

In accordance with some embodiments, openings 118-11 and 118-12 are on neighboring dummy gate stacks 30, and the neighboring ones of openings 118-11 and 118-12 have different lengths L12 and L13 in the Y-direction, with length L12 being greater than length L13. The longer opening 118-12 and the shorter opening 118-13 also extend on neighboring multi-layer stacks 22′, which have middle line MDL-4. In accordance with these embodiments, the longer opening 118-12 is recessed from the middle line MDL-4 by distance ΔS2, which may be in the range between about 1 nm and about 5 nm. The end of the shorter opening 118-13, however, remains aligned to middle line MDL-4, and is not recessed. In addition, the width of the longer opening 118-12 may also be smaller than the width of the shorter opening 118-13, so that due to etching loading effect, in the structures as shown in FIGS. 15C and 21B, the corresponding widths are equal to each other.

In accordance with some embodiments, openings 118-12 and 118-13 are on dummy gate stacks 30 that are further spaced apart from each other by another dummy gate stack 30. The neighboring ones of openings 118-12 and 118-13 have different length L13 and L14, respectively in the Y-direction, with length L13 being smaller than length L14. The longer opening 118-13 and the shorter opening 118-12 also extend on neighboring multi-layer stacks 22′, which have middle line MDL-4. In accordance with these embodiments, the longer opening 118-13 is recessed from the middle line MDL-4 by distance ΔS2, which may be in the range between about 1 nm and about 5 nm. The end of the shorter opening 118-12, however, remains aligned to middle line MDL-4, and is not recessed.

Hard mask 116 is then used to etch-through the underlying dummy gate electrode 34, until dummy gate dielectric 32 is exposed, as shown in FIGS. 13A and 13B. The etching is anisotropic, so that the edges of the dummy gate electrode 34 facing opening 118 are vertical and straight. In the etching process, dummy gate dielectric 32 may be used as an etch stop layer. Dummy gate dielectric 32 is then removed, for example, through an isotropic etching process, so that multi-layer stacks 22′ are revealed. The resulting structure is shown in FIGS. 14A and 14B. The respective process is illustrated as process 226 in the process flow 200 shown as in FIG. 31.

Next, an etching process(es) is performed to remove multi-layer stacks 22′, followed by the further etching of the underlying semiconductor material such as semiconductor strips 20′. The respective process is illustrated as process 228 in the process flow 200 shown as in FIG. 31. Openings 120 are thus formed between neighboring STI regions 26, as shown in FIGS. 15A and 15B. Openings 120 may extend to a level lower than the bottom surfaces of STI regions 26 to reduce leakage. FIG. 15C illustrates the top view of openings 118 in the structure shown in FIGS. 15A and 15B. Openings 120 are not marked, and are inside openings 118 and also at the positions of the original multi-layer stacks 22′.

In accordance with some embodiments, by forming the openings 118 (FIG. 12C) having different widths W1 through W8, and due to the etching loading effect caused by different lengths and different overlapping distances, the openings 118 in FIG. 15C may have equal widths, which are also the widths W1′ through W8′ as shown in FIG. 21A.

FIGS. 15D and 15E illustrate the cross-sectional views 15D-15D and 15E-15E, respectively, of the structure shown in FIG. 15C in accordance with some embodiments. As addressed, the widths of the long openings 118 are reduced to be smaller, while the widths of short openings 120 are not reduced, and thus are greater. The greater widths of the short openings result in deeper openings 120 corresponding to shorter openings 118, and the deeper openings 120 are effective in reducing leakage. In FIG. 15D, the openings 120 corresponding to two short openings 118 are deeper and thus are the main leakage blocker. In FIG. 15E, the openings 120 corresponding to the middle short opening 118 is deeper and thus is the main leakage blocker.

FIGS. 16A and 16B illustrate the filling of openings 118 and 120 to form CPODE isolation region 112. The respective process is illustrated as process 230 in the process flow 200 shown as in FIG. 31. In accordance with some embodiments, the filling process may include depositing a dielectric liner 112A, followed by depositing a dielectric layer 112B on dielectric liner 112A. In accordance with some embodiments, the materials of dielectric liner 112A and dielectric layer 112B may be selected from SiN, SiO, SiON, SiOCN, SiCN, or the like, or combinations thereof. A planarization process such as a CMP process may then be performed to form fin isolation regions 112, which are CPODE isolation regions.

FIG. 16C illustrates the top views of fin isolation regions 112, which include fin isolation regions 112-1, 112-2, 112-3, 112-4, 112-5, 112-6, 112-7, and 112-8. As aforementioned, fin isolation regions 112 may be formed by cutting dummy gate stacks 34. Alternatively, fin isolation regions 112 may be formed in a subsequent stage by cutting/etching replacement gate stacks 70 (FIG. 20), and hence is not formed at this stage. Accordingly, in FIG. 16C, fin isolation regions 112 are shown as being dashed to indicate that they may be, or may not be formed at this time. The dimensions and the relationships of fin isolation regions 112 will be discussed referring to FIGS. 21A and 21B.

When fin isolation regions 112 are formed by cutting/etching replacement gate stacks 70, the processes as shown in FIGS. 11A and 11B through 16A, 16B, and 16C are skipped, and the process proceeds to what is shown in FIGS. 17A and 17B. Dummy gate electrodes 34 and dummy gate dielectrics 32 (and hard masks 36, if remaining) are removed in one or more etching processes, so that recesses 58 are formed, as shown in FIGS. 17A and 17B. The respective process is illustrated as process 232 in the process flow 200 shown as in FIG. 31. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 234 in the process flow 200 shown as in FIG. 31. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH₄OH), or the like may be used to remove sacrificial layers 22A.

Referring to FIGS. 18A and 18B, gate dielectrics 62 and gate electrodes 68 are formed, hence forming replacement gate stacks 70. The respective process is illustrated as process 236 in the process flow 200 shown as in FIG. 31. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

FIG. 18C illustrates a top view of the structure shown in FIGS. 18A and 18B in accordance with some embodiments, assuming the fin isolation regions 112 have not been formed yet. Otherwise, the top view of the resulting structure will be as shown in FIGS. 21A and 21B. The structure shown in FIG. 18C is similar to the structure shown in FIG. 10C, except that the dummy gate stacks 30 in FIG. 10C have been replaced with the replacement gate stacks 70 in FIG. 18C. Nanostructures 22B and the underlying semiconductor strips 20′ have lengthwise direction in the X-direction.

FIGS. 19 and 20 illustrate the formation of fin isolation regions 112 in accordance with some embodiments. The processes are essentially the same as illustrated in FIGS. 11A and 11B through 16A, 16B, and 16C, except that the dummy gate stacks 30 in these Figures are replaced with the replacement gate stacks 70.

Referring to FIG. 19, photoresist 117 and hard mask 116 (also refer to FIGS. 12A and 12B) are formed, with openings 118 (including openings 118-1 through 118-8) being formed therein by etching replacement gate stacks 70 and the underlying semiconductor strips. The parts of the wafer outside of openings 118 are covered by photoresist 117. The respective process is illustrated as process 238 in the process flow 200 shown as in FIG. 31. The details of photoresist 117, hard mask 116, and openings 118 are essentially the same as that in FIGS. 12A, 12B, 12C, and 12D and are not repeated therein. Next, the processes as shown in FIGS. 13A and 13B through FIGS. 15A, 15B, and 15C are performed to form openings 118. FIG. 20 illustrates the openings 118 and 120 in a top view in accordance with some embodiments. The formation process is essentially the same as shown in FIGS. 15A, 15B, and 15C.

Openings 118 and 120 are then filled with a dielectric material(s), so that fin isolation regions 112 are formed. The respective process is illustrated as process 240 in the process flow 200 shown as in FIG. 31. The fin isolation regions 112 are CMODE isolation regions in accordance with these embodiments. The resulting structure is shown in FIGS. 21A and 21B. The cross-sectional views of the resulting structure are essentially the same as that in FIGS. 16A and 16B, except the dummy gate stacks 30 in FIGS. 16A and 16B have been replaced with replacement gate stacks 70.

FIG. 21A illustrates the top views of fin isolation regions 112 in accordance with alternative embodiments. Fin isolation regions 112 include fin isolation regions 112-1, 112-2, 112-3, 112-4, 112-5, 112-6, 112-7, and 112-8, which are formed based on openings 118-1, 118-2, 118-3, 118-4, 118-5, 118-6, 118-7, and 118-8, respectively. Accordingly, fin isolation regions 112 have long fin isolation regions and short isolation regions. The positions and the dimensions of fin isolation regions 112 may be essentially the same as that of openings 118. The lengths (such as L1′, L2′, L3′, L7′ and L8′) of fin isolation regions 112 may be equal to or slightly different from (such as slightly smaller than) the lengths (such as L1, L2, L3, L7 and L8 (FIG. 12C)), respectively, of the corresponding openings 118. The relative relationship between the lengths (such as L1′, L2′, L3′, L7′ and L8′), however, may be the same as the relative relationship of the lengths (such as L1, L2, L3, L7 and L8) of the corresponding openings 118. For example, there may exist the relationships L3′>L2′>L1′ and L7′>L8'.

Similarly, the widths (such as W1′, W2′, W3′, W7′ and W8′) may be equal to or slightly different from (such as slightly smaller than) the widths (such as W1, W2, W3, W7 and W8 (FIG. 12C)), respectively, of the corresponding openings 118. Again, the relative relationship between widths (such as W1′, W2′, W3′, W7′ and W8′) may be the same as the relative relationship of widths (such as W1, W2, W3, W7 and W8) of the corresponding openings 118. For example, there may exist the relationships W3′<W2′<W1′ and W7′<W8′ in accordance with some embodiments, while widths W1′ through W8′ may also be equal to each other.

Throughout an entire device die and wafer 10, in accordance with some embodiments, any two neighboring opening 118 (and any two neighboring fin isolation regions 112), when being immediately neighboring and having their ends close to each other, may cross the same multi-layer stack(s) 22′ to reduce photoresist collapsing.

Also, the difference in the widths W1′, W2′, W3′, W7′ and W8′ (when different from each other) may be resulted from the difference in the thicknesses T1, T2, T3, T7, and T8 of gate spacers 38 in accordance with some embodiments. For example, as shown in FIG. 21A, there may exist the relationship T1<T2<T3 and T7>T8. In accordance with some embodiments, a gate spacer 38 may include an inner layer 38A (FIG. 14B) and an outer layer 38B. In accordance with some embodiments, inner layer 38A comprises silicon nitride, and the outer layer is a low-k dielectric layer formed of, for example, porous SiOCN. In accordance with some embodiments, as shown in FIG. 15B, in the formation of openings 118, outer layer 38B is thinned or removed, while the inner layer 38A remains un-thinned. Accordingly, the difference in thicknesses T1, T2, T3, T7, and T8 may be caused by the difference in thicknesses T38A (FIG. 15B) of different gate spacers 38, while the thicknesses T38B of different gate spacers 38 may be the same as each other.

In addition, in the formation of the fin isolation regions 112 (CMODE regions), openings 118 and the fin isolation regions 112 on the immediately neighboring replacement gate stacks 70 also sideway overlap in the lengthwise direction (Y-direction) and cross the same nanostructures 22B (FIG. 21A), so that some related portions of the photoresist 117 (FIG. 19, also refer to FIGS. 12B, 12C, and 12D) have greater sizes, and are not prone to collapsing and delaminating.

In accordance with some embodiments, by forming the openings 118 (FIG. 12C) having different widths W1 through W8, and due to the loading effect caused by different lengths and different overlapping distances, the resulting widths of fin isolation regions 112 (FIG. 21A), which widths are also the widths of the openings 118 shown in FIG. 15C, may be equal to each other in accordance with some embodiments.

FIG. 21B illustrates the structure that is resulted from the structure as shown in FIG. 12D. In accordance with these embodiments, the fin isolation regions 112-9 and 112-10 have the same length L10 and L11 (refer to FIG. 12D), and thus the ends of both of fin isolation regions 112-9 and 112-10 are recessed from the respective middle line MDL-3 for the same distance ΔS1. On the other hand, fin isolation region 112-12 is longer than fin isolation region 112-13, and thus the end of the longer fin isolation region 112-12 is recessed from the middle line MDL-4 by recessing distance ΔS2, while the end of the shorter fin isolation region 112-12 is not recessed, and is aligned to the middle line MDL-4. Similarly, fin isolation region 112-13 is longer than fin isolation region 112-12, and thus the end of the longer fin isolation region 112-13 is recessed, while the end of the shorter fin isolation region 112-12 is not recessed, and is aligned to the middle line MDL-4.

Next, as also shown in FIGS. 22A and 22B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 22A and 22B, ILD 76 is deposited over ILD 52 and over gate masks 74. The respective process is illustrated as process 242 in the process flow 200 shown as in FIG. 31. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

In FIGS. 23A and 23B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process(es), such as RIE, NBE, or the like.

After the recesses are formed, silicide regions 78 are formed over source/drain regions 48. The respective process is illustrated as process 244 in the process flow 200 shown as in FIG. 31. Contact plugs 80B are then formed over silicide regions 78. Also, contacts 80A (may also be referred to as gate contact plugs) are formed in the recesses, and are over and contacting gate electrodes 68. The respective process is illustrated as process 246 in the process flow 200 shown as in FIG. 31. Transistor 82 is thus formed. Although FIG. 23B illustrates that contact plugs 80A and 80B are in a same cross-section, in various embodiments, contact plugs 80A and 80B may be formed in different cross-sections, thereby reducing the risk of shorting with each other.

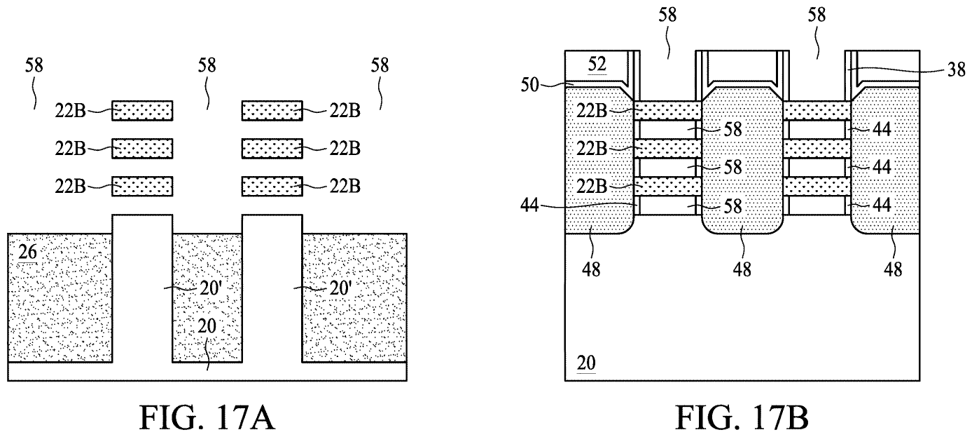

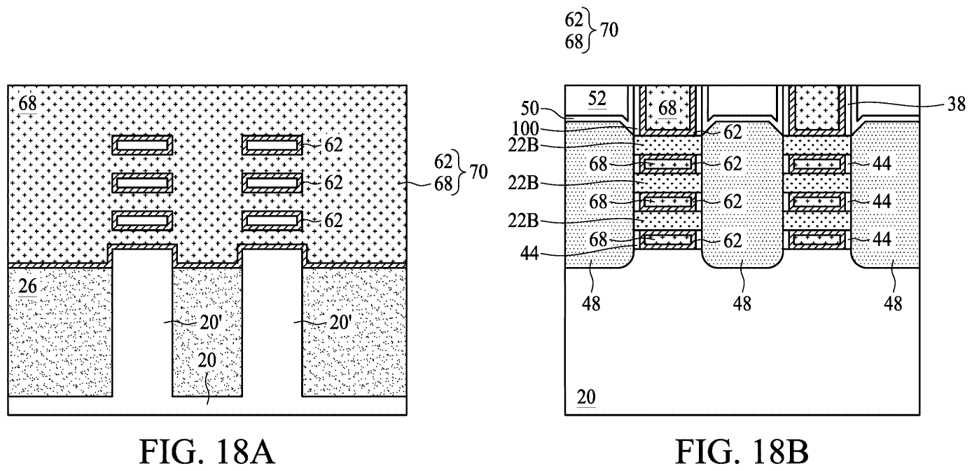

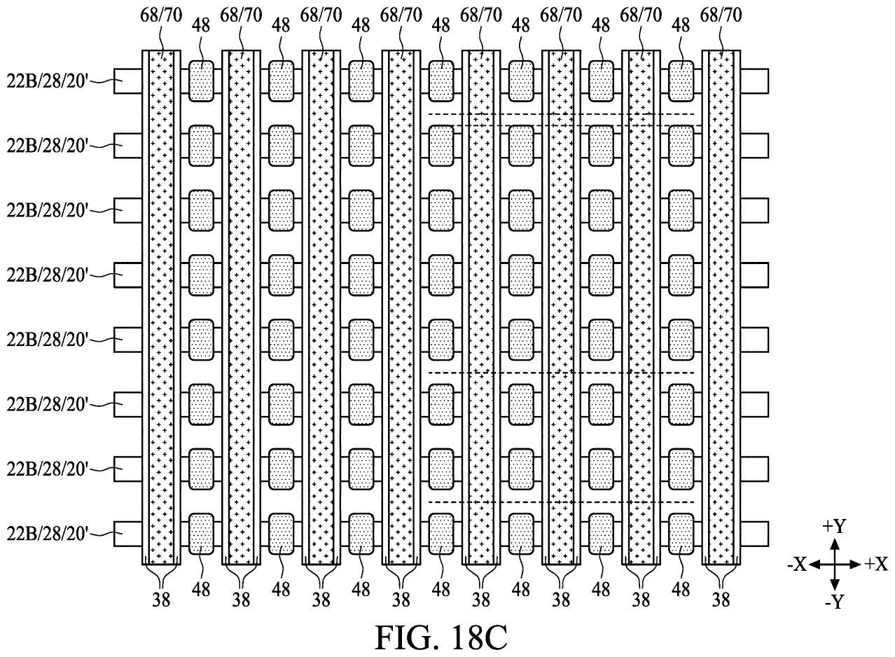

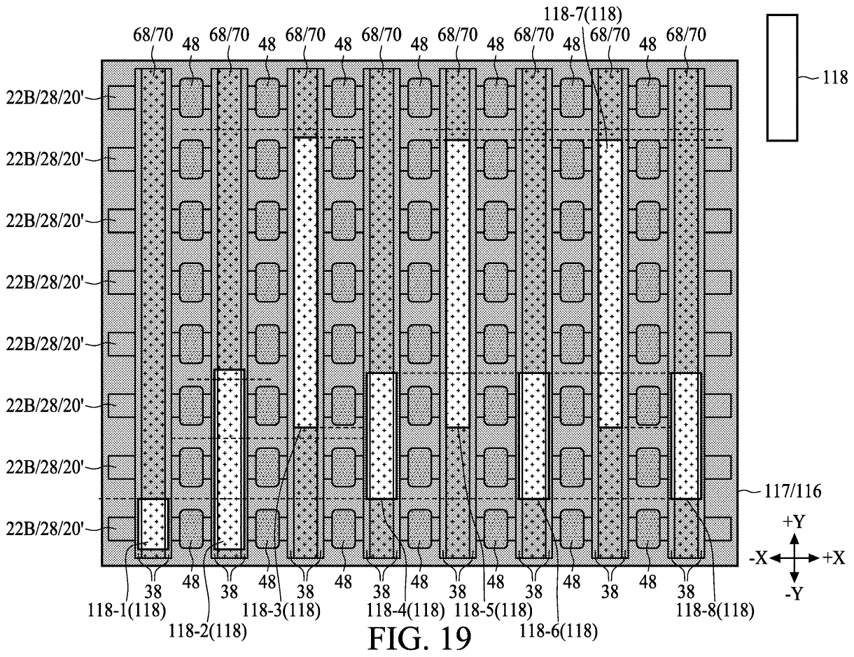

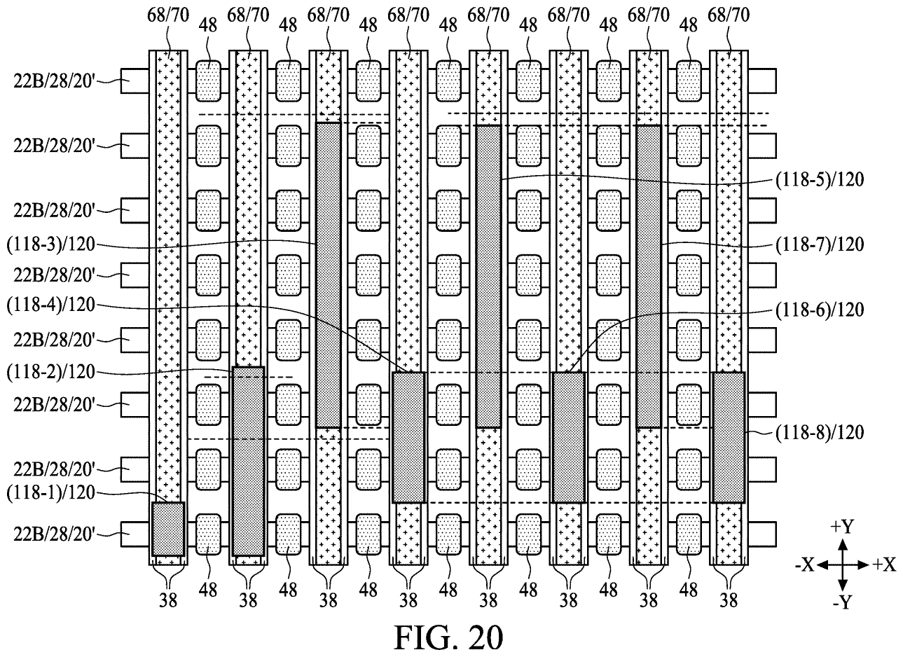

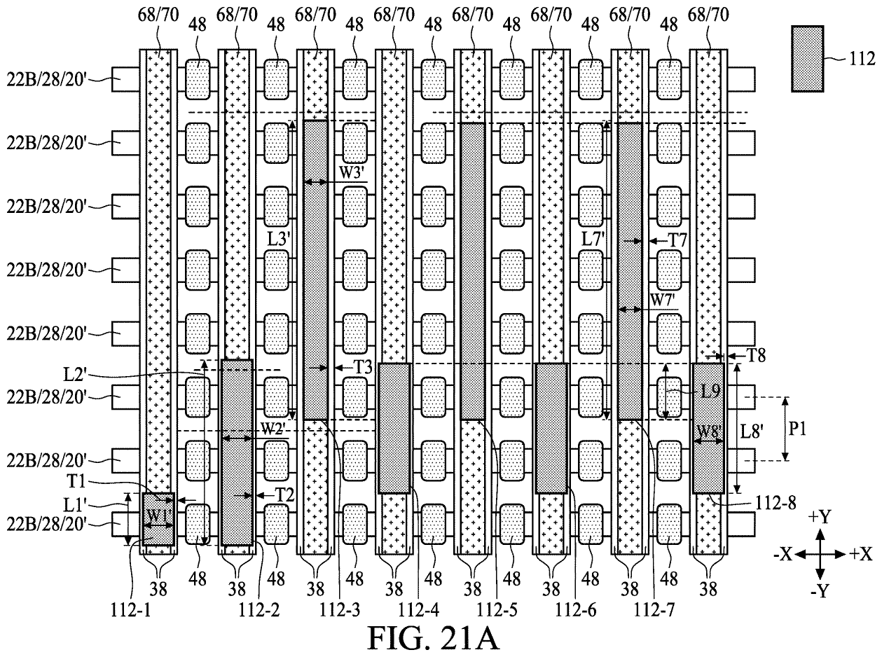

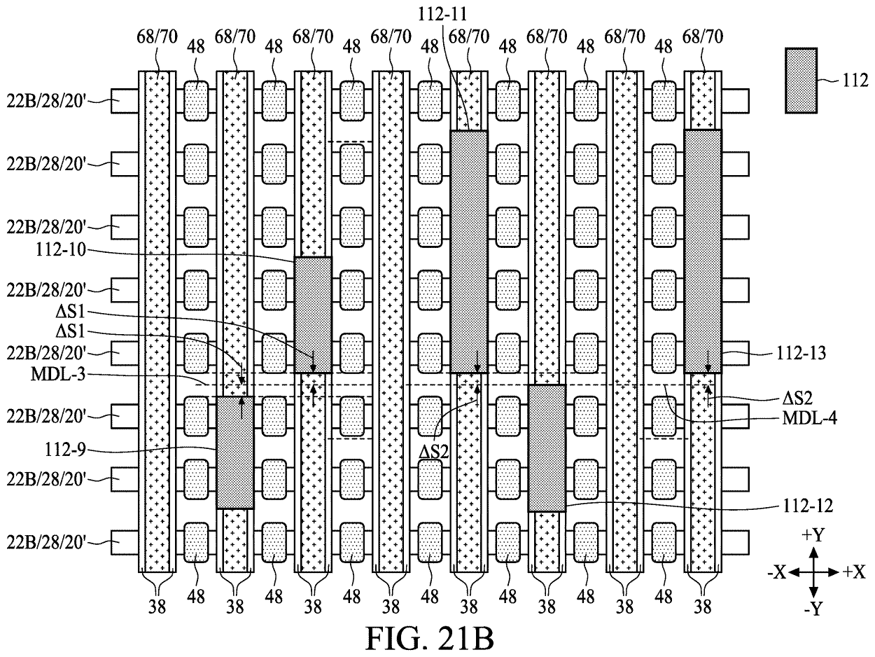

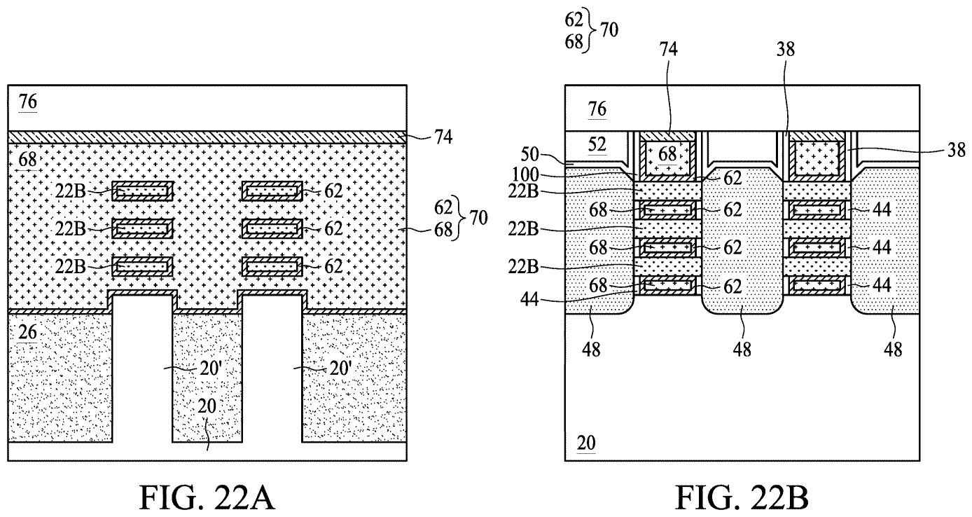

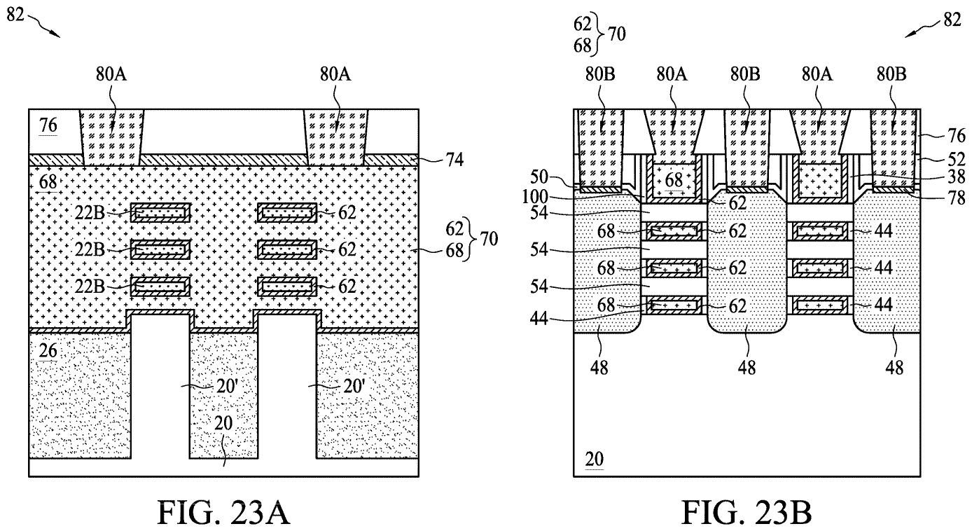

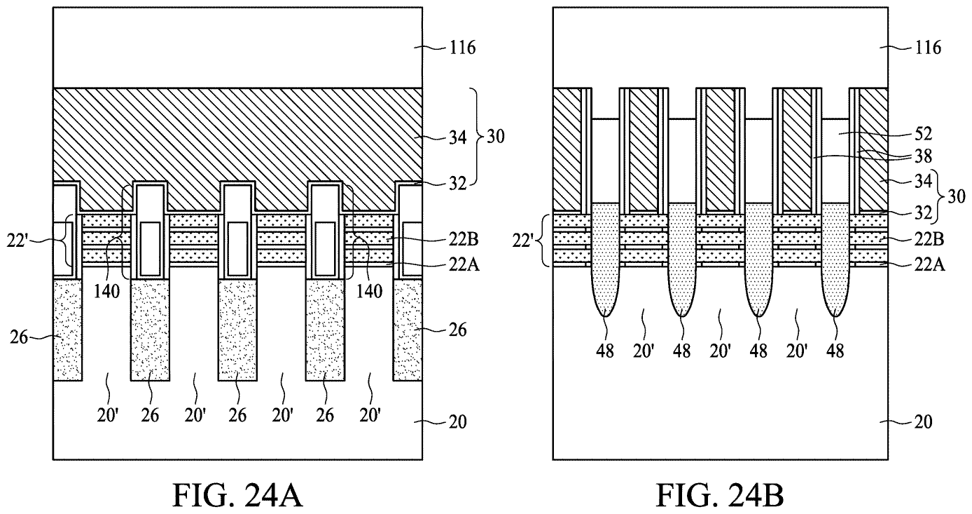

FIGS. 24A and 24B through 30A and 30B illustrate the formation of fin isolation region 112 in accordance with alternative embodiments. These embodiments are essentially the same as that shown in FIGS. 11A and 11B through 16A and 16B, except that dummy fins are formed so that when gate stacks are cut by forming gate isolation regions (also referred to as Cut-Metal Gate (CMG) regions) into shorter portions, the gate isolation regions may land on the dummy fins. Referring to FIGS. 24A and 24B, dummy fins 140 are formed over STI regions 26, with dummy gate stacks 30 being formed on the dummy fins 140. Dummy fins 140 may have a multi-layer structure formed of dielectric materials such as SiN, SiO, SiOCN, and or the like, and may comprise high-k dielectric materials. Hard mask 116 is formed over dummy gate electrode 34.

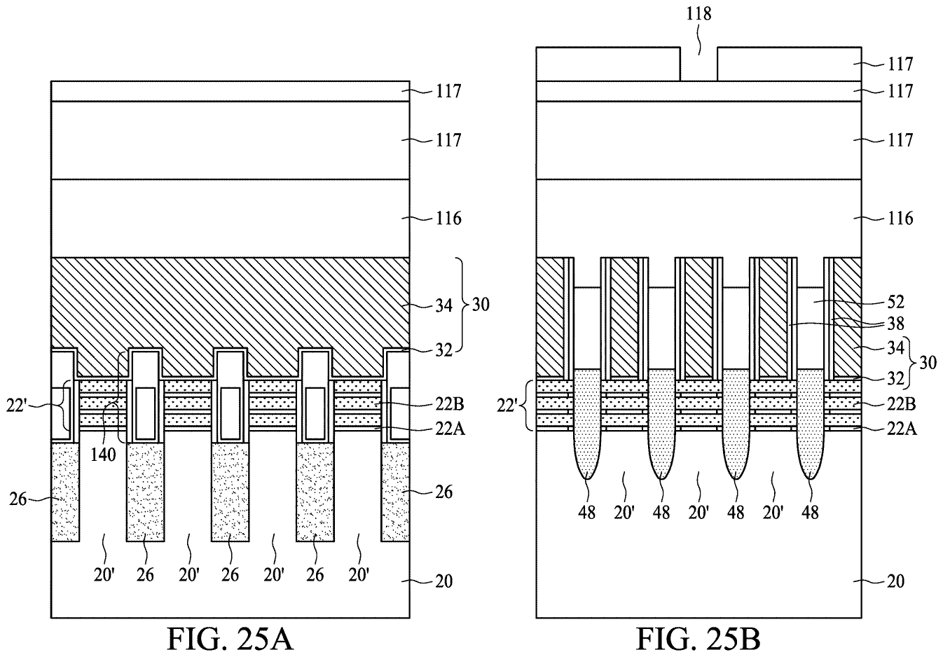

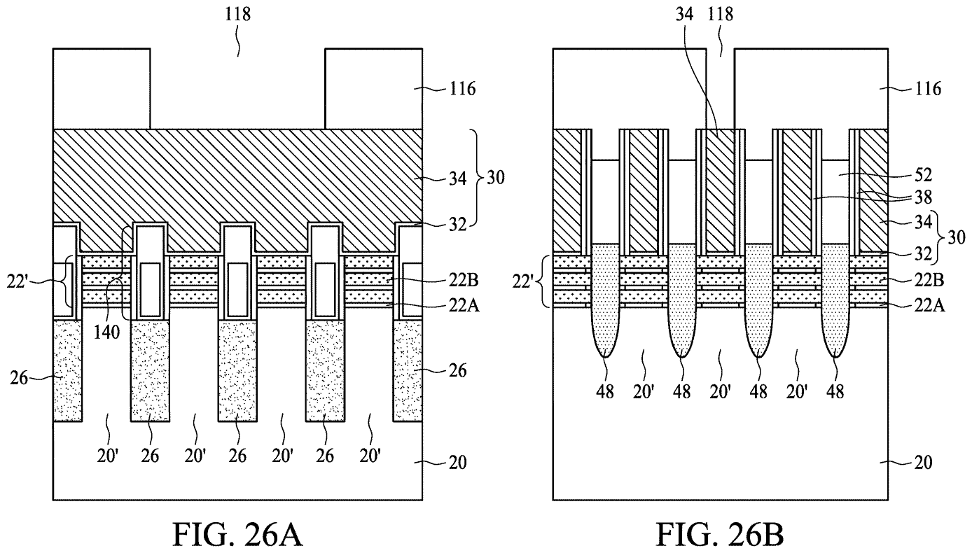

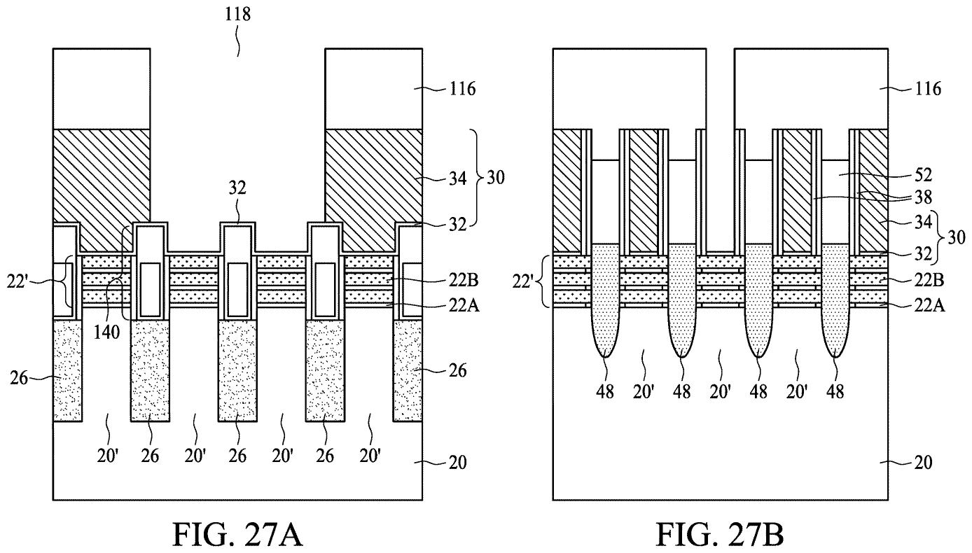

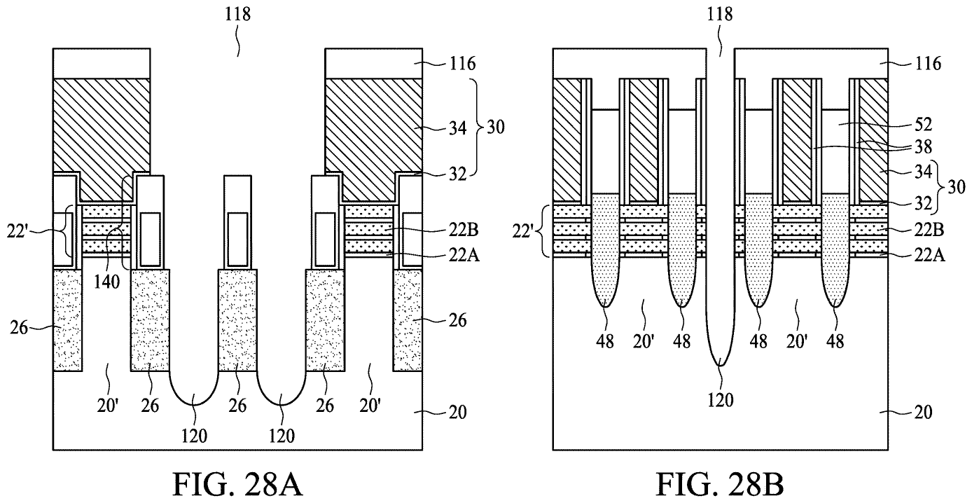

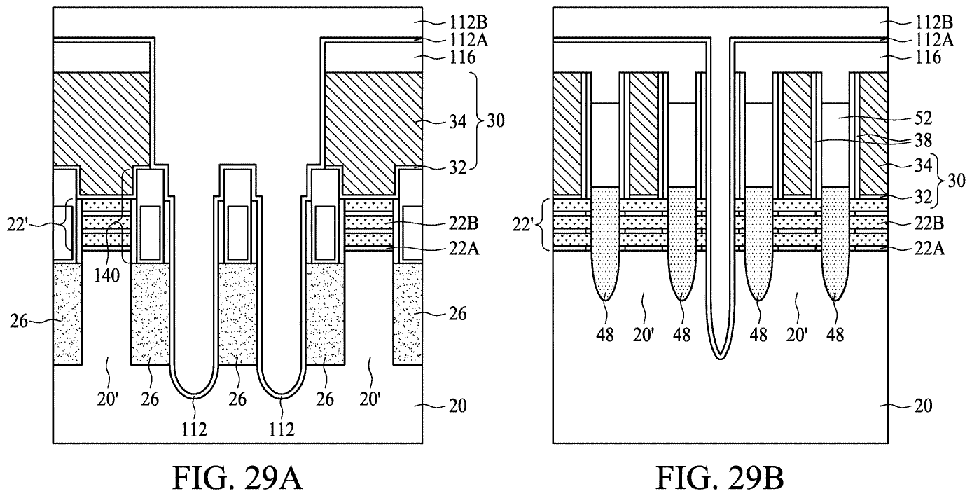

FIGS. 25A and 25B illustrate the formation of etching mask 117, in which openings 118 are formed. The openings 118 may be essentially the same as shown in FIG. 12C. Next, as shown in FIGS. 26A and 26B, hard mask 116 is etched, so that openings 118 extend into hard mask 116, the remaining portions of the etching mask 117 are removed. FIGS. 27A and 27B illustrate the etching of dummy gate electrodes 34. FIGS. 28A and 28B illustrate the etching of dummy gate dielectric 32, multi-layer stacks 22′, and the underlying semiconductor strips 20', so that openings 120 are formed. Next, as shown in FIGS. 29A and 29B, dielectric liners 112A and dielectric layer 112B are deposited, and may be formed of the material selected from SiN, SiO, SiON, SiCN, SiOCN, and the like.

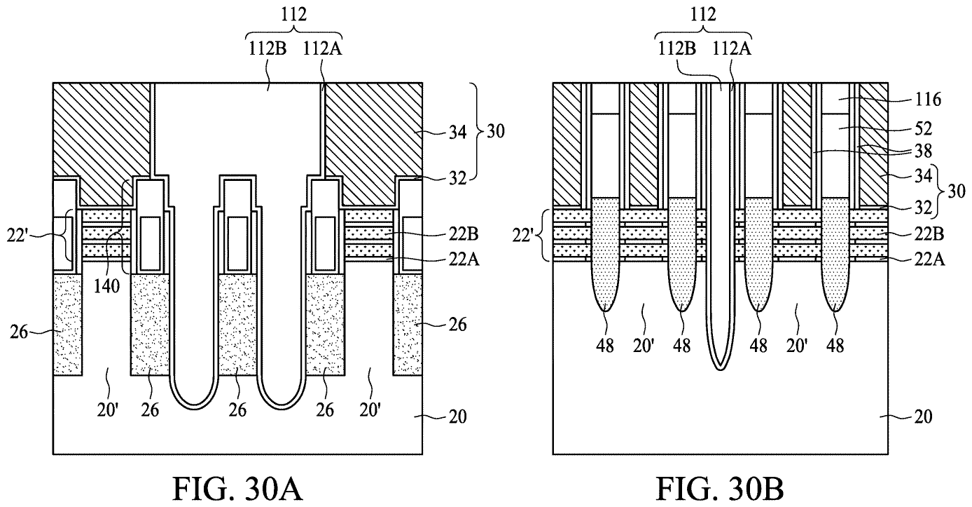

A planarization process is then performed to remove excess portions of dielectric liners 112A and dielectric layer 112B, leaving fin isolation regions 112 as shown in FIGS. 30A and 30B.

The embodiments of the present disclosure have some advantageous features. By forming fin isolation regions (CPODE or CMODE isolation regions) on neighboring gate stacks extending toward each other and cross a same multi-layer stack(s) (and a same semiconductor nanostructure(s)), and further adjusting the dimensions of the fin isolation regions (and the corresponding openings in the corresponding photoresist), the collapsing and the delamination of the corresponding photoresist is reduced.

In accordance with some embodiments of the present disclosure, a method comprises forming a plurality of semiconductor regions having first lengthwise directions parallel to a first direction; forming a plurality of gate stacks having second lengthwise directions parallel to a second direction perpendicular to the first direction, wherein the plurality of gate stacks are on first portions of the plurality of semiconductor regions; etching the plurality of gate stacks to form a plurality of openings in the plurality of gate stacks, wherein the plurality of openings comprise a first opening in a first gate stack of the plurality of gate stacks; and a second opening in a second gate stack of the plurality of gate stacks, wherein the first opening and the second opening are immediately neighboring each other and have a sideway overlap with an overlap distance equal to or greater than a pitch of the plurality of semiconductor regions, and wherein the overlap distance is parallel to the second lengthwise directions; etching the plurality of semiconductor regions exposed through the plurality of openings to extend the plurality of openings downwardly to be between dielectric isolation regions; and filling the plurality of openings to form fin isolation regions.

In an embodiment, wherein the overlap distance is equal to or greater than two times the pitch. In an embodiment, the etching the plurality of gate stacks comprises etching a plurality of dummy gate stacks, and the method further comprises, after the fin isolation regions are formed, replacing remaining portions of the dummy gate stacks with replacement gate stacks. In an embodiment, the etching the plurality of gate stacks comprises etching a plurality of replacement gate stacks. In an embodiment, the first opening has a first length and a first width, and the second opening has a second length and a second width, and wherein the first length is greater than the second length, and the first width is smaller than the second width.

In an embodiment, the method further comprises forming a patterned photoresist comprising a first additional opening and a second additional opening, wherein the first opening is formed by etching a first part of the first gate stack directly underlying the first additional opening, the second opening is formed by etching a second part of the second gate stack directly underlying the second additional opening, and wherein the first additional opening has a third length and a third width, and the second additional opening has a fourth length and a fourth width, wherein the third length is greater than the fourth length, and the third width is smaller than the fourth width. In an embodiment, a first end of the first opening is misaligned from a middle point of two first neighboring source/drain regions, and a second end of the second opening is aligned to an additional middle point of two second neighboring source/drain regions.

In an embodiment, the method further comprises forming dummy fins overlapping the dielectric isolation regions, wherein after the plurality of gate stacks are etched, the dummy fins are exposed to the plurality of openings. In an embodiment, the fin isolation regions comprise a first fin isolation region in the first opening, and a second fin isolation region in the second opening, and wherein both of the first fin isolation region and the second fin isolation region intersect a same semiconductor region of the plurality of semiconductor regions. In an embodiment, the method further comprises forming an epitaxy region, wherein the epitaxy region is between the first gate stack and the second gate stack and on the same semiconductor region.

In an embodiment, the epitaxy region is fully encircled by dielectric materials. In an embodiment, portions of the plurality of semiconductor regions and the plurality of gate stacks form a plurality of transistors, and the epitaxy region and a plurality of source/drain regions of the plurality of transistors are formed in a common epitaxy process.

In accordance with some embodiments of the present disclosure, a structure comprises a plurality of semiconductor regions; a first gate stack and a second gate stack immediately neighboring each other; a first fin isolation region in the first gate stack; a second fin isolation region in the second gate stack, wherein the first fin isolation region and the second fin isolation region have a sideway overlap having an overlap distance being equal to or greater than a pitch of the plurality of semiconductor regions, and wherein the overlap distance is measured in a direction parallel to lengthwise directions of the first gate stack and the second gate stack; and a plurality of source/drain regions on opposing sides of the first gate stack and the second gate stack to form a plurality of transistors.

In an embodiment, the plurality of semiconductor regions comprise semiconductor nanostructures. In an embodiment, the structure further comprises a semiconductor region between the first gate stack and the second gate stack, wherein the semiconductor region comprises facets, and the semiconductor region is formed of a same semiconductor material as the plurality of source/drain regions. In an embodiment, the overlap distance is equal to multiple times of the pitch.

In accordance with some embodiments of the present disclosure, a structure comprises an elongated semiconductor region comprising a plurality of portions, wherein the elongated semiconductor region comprises a first semiconductor material; a first gate stack and a second gate stack immediately neighboring each other; an epitaxy semiconductor region between and contacting a first portion and a second portion of the elongated semiconductor region, wherein the epitaxy semiconductor region comprises a second semiconductor material different from the first semiconductor material; a first dielectric isolation region in the first gate stack; and a second dielectric isolation region in the second gate stack, wherein both of the first dielectric isolation region and the second dielectric isolation region intersect the elongated semiconductor region.

In an embodiment, in a top view of the structure, the epitaxy semiconductor region is surrounded by dielectric materials. In an embodiment, the first dielectric isolation region is longer than, and is narrower than, the second dielectric isolation region. In an embodiment, the elongated semiconductor region comprises a nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor regions, wherein in a top view of the plurality of semiconductor regions, the plurality of semiconductor regions have first lengthwise directions parallel to a first direction;
forming a first gate stack and a second gate stack having second lengthwise directions parallel to a second direction perpendicular to the first direction, wherein the first gate stack and the second gate stack cross over the plurality of semiconductor regions; and
forming a first dielectric isolation region and a second dielectric isolation region to cut the first gate stack and the second gate stack, respectively, wherein the first dielectric isolation region is shorter, and is wider, than the second dielectric isolation region.

2. The method of claim 1, wherein the first dielectric isolation region and the second dielectric isolation region penetrate through respective underlying shallow trench isolation regions to extend into a bulk semiconductor substrate.

3. The method of claim 1, wherein the first gate stack and the second gate stack are formed by processes comprising:
etching the first gate stack and the second gate stack to form a first opening and a second opening, wherein the first opening is shorter, and is wider, than the second opening; and
filling the first opening and the second opening with dielectric materials.

4. The method of claim 3, wherein in an etching process for etching the first gate stack, a first gate spacer on a sidewall of the first gate stack is thinned.

5. The method of claim 4, wherein in the etching process, a second gate spacer on a sidewall of the second gate stack is unetched.

6. The method of claim 1, wherein the first gate stack and the second gate stack are dummy gate stacks.

7. The method of claim 1, wherein the first gate stack and the second gate stack are replacement gate stacks.

8. The method of claim 1 comprising forming dummy fins, wherein the first gate stack and the second gate stack are over the dummy fins.

9. The method of claim 1, wherein a first end of the second dielectric isolation region is between two first neighboring source/drain regions, and is recessed from a first middle point of the two first neighboring source/drain regions.

10. The method of claim 9, wherein a second end of the first dielectric isolation region is between two second neighboring source/drain regions, and is aligned to a second middle point of the two second neighboring source/drain regions.

11. The method of claim 1, wherein the plurality of semiconductor regions are semiconductor fins that protrude higher than respective shallow trench isolation regions, with the respective shallow trench isolation regions being on opposite sides of the respective ones of the plurality of semiconductor regions.

12. A method comprising:
forming a plurality of semiconductor regions that are elongated in a top view of the plurality of semiconductor regions, wherein the plurality of semiconductor regions are parallel to each other;
forming a plurality of source/drain regions starting from the plurality of semiconductor regions;
forming a first gate stack and a second gate stack that are elongated in the top view and parallel to each other, wherein the first gate stack and the second gate stack cross over the plurality of semiconductor regions; and
replacing portions of the first gate stack and the second gate stack to form a first dielectric isolation region and a second dielectric isolation region, respectively, wherein the first dielectric isolation region is wider than the second dielectric isolation region.

13. The method of claim 12, wherein the first gate stack is shorter than the second gate stack.

14. The method of claim 12 further comprising:
first gate spacers on opposite sides of the first dielectric isolation region; and
second gate spacers on opposite sides of the second dielectric isolation region, wherein the first gate spacers are thinner than the second gate spacers.

15. The method of claim 12 further comprising forming an epitaxy region, wherein the epitaxy region is between the first gate stack and the second gate stack.

16. The method of claim 15, wherein the epitaxy region is fully encircled by dielectric materials.

17. A method comprising:
etching a first gate stack and a second gate stack to form a first opening and a second opening, respectively, wherein the first opening is wider than the second opening;
etching a first protruding fin and a second protruding fin that are underlying and exposed to the first opening and the second opening;
etching a first semiconductor strip and a second semiconductor strip that are underlying and exposed to the first opening and the second opening; and
filling the first opening and the second opening to form a first fin isolation region and a second fin isolation region, respectively.

18. The method of claim 17 further comprising replacing the first gate stack and the second gate stack with replacement gate stacks.

19. The method of claim 17, wherein the first opening is shorter than the second opening.

20. The method of claim 17, wherein a first gate spacer and a second gate spacer comprise sidewalls exposed to the first opening and the second opening, respectively, and wherein in a top view of the first gate spacer and the second gate spacer, the first gate spacer is thinner than the second gate spacer.
